(19) United States
(12) Patent Application Publication
(10) Pub. No.: US 2016/0293829 A1
(43) Pub. Date: Oct. 6, 2016

(54) PIEZOELECTRIC SWITCH WITH LATERAL MOVING BEAMS

(71) Applicant: 19th Space Electronics, Dallas, TX (US)

(72) Inventors: Lizon Maharjan, Richardson, TX (US); Joseph Hearron, Sachse, TX (US); Job Timothy Brunet, Arlington, TX (US); Arash Hassanpour Isfahani, Dallas, TX (US); Carlos Caicedo-Narvaez, Dallas, TX (US)

(73) Assignee: 19TH SPACE ELECTRONICS, Dallas, TX (US)

(21) Appl. No.: 14/675,943

(22) Filed: Apr. 1, 2015

(51) Int. Cl. H01L 41/09; H01H 57/00

(52) U.S. Cl. CPC H01L 41/0933; H01H 57/00

(57) ABSTRACT

A piezoelectric switching element includes an actuator and multiple piezoelectric-morphing beams. The actuator includes a conducting head and an actuator stem, and each piezoelectric-morphing beam includes a beam contact head of conductive material and a beam stem manufactured out of bimorph material. A control voltage is selectively applied to electrical contacts coupled to the beam stems to create a piezoelectric effect that axially stretches the selected piezoelectric-morphing beam to push the beam contact head along a single axis of movement toward the actuator conducting head to create an electrical connection between the contact head and the conducting head. A controller signals which piezoelectric-morphing beam to connect to the actuator. This multi-piezoelectric switching element can be affixed to the electrical terminals of different electrical components (e.g., a transistor) to create an electrical cell that can be manufactured on a semiconductor chip or in a microelectromechanical system (MEMS) device.

### BACKGROUND

Piezoelectric materials deform and move when an external voltage is applied to them. When the external voltage is applied, a piezoelectric effect takes place as a result of the crystal lattice structure of the piezoelectric materials. Crystals generally have a charge balance where negative and positive charges precisely cancel each other out along the rigid planes of the crystal lattice. When this charge balance is disrupted by applying physical stress to a crystal, the energy is transferred by electric charge carriers, creating a current in the crystal. With the converse piezoelectric effect, application of an external electric field to the crystal disrupts the neutral charge state, resulting in mechanical stress and readjustment of the lattice structure. This mechanical stress and readjustment causes the piezoelectric material to physically move in one or more directions.

Modern discrete electrical circuit components are generally fixed with a specific number of input connecting terminals that need to be hardwired to circuit component. For example, circuits often use transistors and diodes that need to be connected to resistors and voltage sources to create a fully functioning circuit. Hardwiring the transistors and diodes in this manner limits the voltages and currents supplied to them to whatever is provided from upstream circuitry. Consequently, the transistors the transistor and diode cannot change on-the-fly the source of the voltage or current it receives at one of its contact points, making the transistor or diode stuck with the hardwired source.

### SUMMARY

This Summary is provided to introduce a selection of concepts in a simplified form that are further described below in the Detailed Description. This Summary is not intended to identify key or essential features of the claimed subject matter, but instead is provided to illustrate different embodiments.

One embodiment is directed to a piezoelectric switching element, referred to herein as a “piezoelectric multiplexer,” that includes an actuator and a plurality of parallel piezoelectric-morphing beams. The actuator includes a conducting head fashioned out of a conducting material and a non-conducting actuator stem. Each piezoelectric-morphing beam has a contact head similarly fashioned out of a conducting material and a beam stem manufactured out of a piezoelectric-morphing material. The contact heads are electrically coupled to various circuit voltage or current supplies and can be selectively brought into contact with the actuator's conducting head through application of a control voltage by a control circuit. The control voltage is strong enough to create a piezoelectric effect in the piezoelectric-morphing stems, thereby causing the bimorph beam to axially move (or stretch) along a vertical or horizontal axis toward the actuator and bring one of the contact heads into contact with the conducting head of the actuator. The contact and conducting heads, both being made from conducting material, create an electrical connection when they are touching. The electrical connection allows voltage and current to pass through the touching heads. Thus, the piezoelectric-morphing stems selectively push the contact and conducting heads into contact with each to create an electrical connection and pull the contact and conducting heads apart to sever the electrical connection, creating a switch that can create multiple electrical connections with the actuator using the various piezoelectric-morphing beams.

In one embodiment, the actuator and piezoelectric-morphing beams of the piezoelectric multiplexer are positioned on top of a dielectric layer of a semiconductor chip, with the conducting and contact heads respectively oriented atop upright stems of the actuator and piezoelectric-morphing beams. In one embodiment, the actuator is centered in the middle of a geometric pattern of bimorph beams. The piezoelectric-morphing beams may form a triangle, circle, square, rectangle, trapezoid, pentagon, hexagon, or other geometric shape around the actuator.

Another embodiment is directed to a cell with multiple piezoelectric multiplexers coupled to different terminals of an electrical component. Two piezoelectric multiplexers may be coupled to a two-terminal component (e.g., a diode), three piezoelectric switching elements may be coupled to a three-terminal component (e.g., a transistor), four piezoelectric multiplexers may be coupled to a four-terminal component (e.g., a bridge converter), and so on. One specific embodiment relates to a transistor with its collector, base and emitter (or source, base and drain) terminals connected to different piezoelectric multiplexers.

Another embodiment is directed to a switching element that includes an actuator with an actuator conducting head and a piezoelectric-morphing beam positioned proximate to the actuator. The piezoelectric-morphing beam includes a beam contact head made of a conductive material and a beam stem made of a piezoelectric-morphing material that is capable of being extended along a vertical or horizontal axis through application of a control voltage signal. A controller is configured to selectively apply the voltage signal to the piezoelectric-morphing material to consequently cause the piezoelectric-morphing material to axially extend the beam stem toward the actuator and bring the beam contact head into physical contact with the conducting head.

### BRIEF DESCRIPTION OF THE DRAWINGS

Embodiments are illustrated by way of example in the accompanying figures wherein:

FIG. 1A is a diagram of a piezoelectric-morphing switching element to axially move in the vertical direction.

FIG. 1B is a diagram of a piezoelectric-morphing switching element to axially move in the horizontal direction.

FIG. 1C is a diagram of a piezoelectric-morphing switching element to axially move in the horizontal direction.

FIG. 2 is a diagram of a piezoelectric-morphing switching element with piezoelectric-morphing beams surrounding a triangular actuator.

FIG. 3A is a diagram of a transistor with multiple piezoelectric-morphing switching elements attached to separate terminals.

FIG. 3B is a block diagram of a two-terminal electrical component coupled to piezoelectric-morphing switching elements.

FIG. 3C is a block diagram of a three-terminal electrical component coupled to piezoelectric-morphing switching elements.

FIG. 3D is a block diagram of a four-terminal electrical component coupled to piezoelectric-morphing switching elements.

FIG. 4A is a block diagram of a transistor with multiple piezoelectric-morphing switching elements.

FIG. 4B is a schematic drawing of a transistor with multiple piezoelectric-morphing switching elements providing the ability to switch between different terminal inputs.

FIG. 5 illustrates a switching element configured to move in two directions along a single axis of movement.

### DETAILED DESCRIPTION

Embodiments described herein generally related to a piezoelectric switch or multiplexer with a single actuator beam with an affixed conducting head that is flanked or surrounded by proximately positioned piezoelectric-morphing beams affixed with electrically conductive contact heads. Each of the piezoelectric-morphing beams includes a beam stem that can be stretched along an axis to move the affixed contact head of the piezoelectric-morphing beam into contact with the actuator's affixed conducting head. The conducting head also comprises an electrically conductive material. So when the two heads physically touch each other, an electrical connection is made, and current or voltage being supplied to the piezoelectric-morphing beam's contact head is passed through the actuator's conducting head.

Having multiple piezoelectric-morphing beams with contact heads that can similarly be moved into contact with the actuator's conducting head creates a new switching device that can selectively switch between different nodes of a circuit. For example, a gate of a transistor may be connected to the conducting head of the actuator, and three different circuit nodes pay be respectively connected to the contact heads of three different piezoelectric-morphing beams. The contact heads of the piezoelectric-morphing beams can selectively be brought into contact with the conducting head of the actuator to switch the portion of a circuit supplied to the transistor gate. This effectively provides a way to multiplex the different circuit nodes into contact with the transistor without having to use a traditional multiplexer.

The beam stems of the piezoelectric-morphing beams are manufactured out of a piezoelectric material that morph when a control voltage is applied thereto. The piezoelectric-morphing beams are positioned in the embodiments disclosed herein so that the application of a control voltage to the beam stems causes the stems to move axially in one direction, which may be either vertically, horizontally, or at an angle of inclination or declination. As discussed herein, axial movement refers to a beam stem being stretched or shrunk along a single axis in a vertical, horizontal, inclined, or declined direction. Axial movement does not include a bending of the beams along multiple axes, e.g., bending both horizontally and vertically.

Also, the term “piezoelectric-morphing,” as used herein, refers to a component with a piezoelectric segment that operatively moves in along a single axis when a control voltage, current, or power signal is applied to the piezoelectric material. The beam stems disclosed herein comprise a piezoelectric material and are therefore piezoelectric-morphing upon application of a control signal. These beam stems can be made in a uni-morph piezoelectric manner, bimorph piezoelectric manner (consisting of two uni-morph piezoelectric layers), or the like.

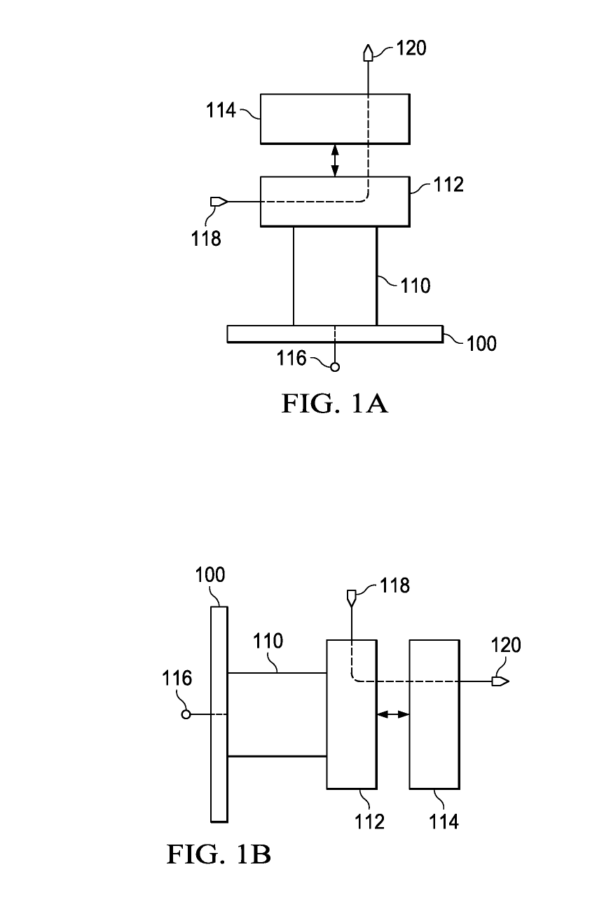

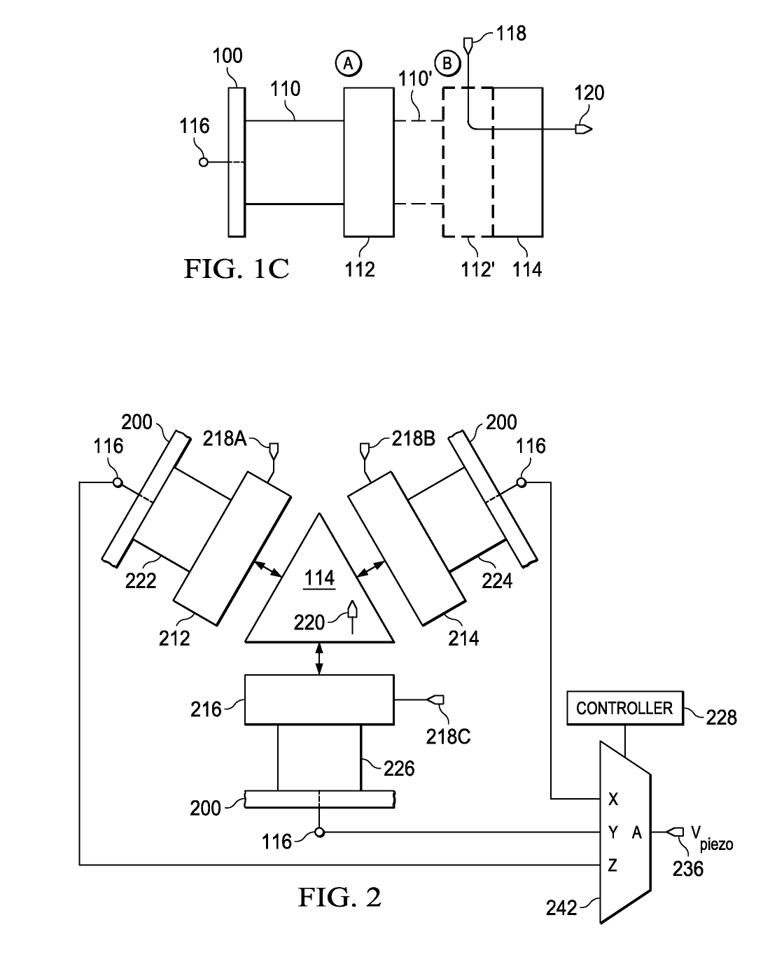

FIG. 1A is a diagram of a piezoelectric-morphing switching element 100 to axially move in the vertical direction. The switching element 100 includes a piezoelectric-morphing beam 110 with a physically connected contact head 112 that is oriented proximate to an electrically conductive conducting head 114 with an air gap separating the two heads 112 and 114. The piezoelectric-morphing beam 110 is positioned in an upright manner, attached at one end to a base layer of the switching element 100 and the opposite end affixed to the contact head 112. The conducting head 114 is oriented overhead of the contact head 112. The contact head 112 and the conducting head 114 comprise, or at least include, a conducting material (e.g., copper, aluminum, etc.), and the piezoelectric-morphing beam 110 is made of a piezoelectric-morphing material (e.g., lead zirconate titanate or the like). The actuator's conducting head 114 may be affixed to insulating, conducting, or piezoelectric-morphing materials; though, such affixation is not shown for the sake of clarity.

In one embodiment, piezoelectric material in beam 110 creates a piezoelectric effect when a control voltage, current, or power signal is applied to application node 116. For the sake of clarity, the control voltage, current, or power signal applied to cause such a piezoelectric effect in the piezoelectric-morphing beam 110 is collectively referred to herein as “Vpiezo.” Continuing on with the aforesaid embodiment, the piezoelectric effect causes the piezoelectric-morphing beam to stretch along an axis in the vertical direction—as indicated by the depicted arrows demonstrating the axis of movement—to physically move the contact head 112 into contact with the conducting head 114. The contact head 112 is also electrically coupled to a particular circuit node 118, and when the contact head 112 and conducting head 114 are physically touching, the two create an electrical connection for voltage and current at node 118 to pass to a second circuit node 120 that is electrically coupled to the conducting head 114. As a result, voltage or current at 118 can pass through contact head 112 and conducting head 114 and out to node 120.

The piezoelectric-morphing beam 110 includes one end that is attached to a base layer of the switching element 100, referred to as “base end,” and a “contact end” that is affixed to the contact head 112. A single “axis of movement,” which may be vertical, horizontal, inclined, or declined, depending on the orientation of the piezoelectric-morphing beam 110, spans from the base end, through the piezoelectric-morphing beam 110, and out the contact end. In one embodiment, the piezoelectric-morphing beam 110 moves along this single axis of movement when a piezoelectric effect is create or felt in the piezoelectric-morphing beam 110. It should be noted, however, that a piezoelectric effect may cause the piezoelectric-morphing beam 110 to shrink or expand along a second, perpendicular axis as the piezoelectric-morphing beam 110 stretches and retracts. For the sake of clarity, however, the piezoelectric-morphing beam 110 only moves the contact head 112 in a single axial direction, either toward or away from the conducting head 114. Thus, in one embodiment, the piezoelectric-morphing beam 110 moves, (i.e., stretches, shrinks, pushes, retracts, etc.) the contact head 112 axially along a single axis of movement—either horizontally or vertically—even though a piezoelectric effect in the piezoelectric-morphing beam 110 may actually cause the beam 110 to stretch and shrink along two axes. In other words, in one embodiment, the contact head 112 is only moved in one axial direction and is not moved along a multi-axis or arcuate path.

The electrical connection between the contact head 112 and the conducting head 114 can be severed by withdrawing or reducing the control signal applied to node 116, resulting in the piezoelectric-morphing beam 110 to shrink back to its original non-morphed state and thereby move the affixed contact head 112 downward and out of contact with the conducting head 114. Thus, the control signal can be applied to node 116 to cause the piezoelectric-morphing beam 110 to stretch vertically or removed to cause the piezoelectric-morphing beam 110 to shrink back downward in order to selectively create an electrical connection between nodes 118 and 120 when desired.

In one embodiment, an electrical contact to node 116 is coupled to the piezoelectric-morphing beam 110 through a metallization or dielectric layer—the latter being through a connecting via or pathway—of a semiconductor chip or microelectromechanical system (MEMS). Other embodiments make such electrical contact to node 116 through hardwiring or other well-known fabrication methods.

FIG. 1B is a diagram of the piezoelectric-morphing switching element 100 to axially move in the horizontal direction. In this embodiment, application of Vpiezo to node 116 causes the piezoelectric-morphing beam 110 to axially stretch in the horizontal direction, as shown by the depicted arrows showing the axis of movement. In this depicted embodiment, the contact head 112 is horizontally pushed along a single axis of movement extending from base end of the switching element through the contact head 112 into contact with conducting head 114 to create an electrical connection between nodes 118 and 120. FIG. 1C illustrates this, showing piezoelectric-morphing beam 110 resting at position A and then horizontally moving (shown as 110′) contact head 112′ along a single axis of movement into contact with conducting head 114 at position B.

FIGS. 1A-1C show the contact head 112 configured for movement along a vertical or horizontal axis of movement. Alternative embodiments move the contact head 112 in a single axis of movement at an angle of inclination or declination.

FIG. 2 is a diagram of a piezoelectric-morphing switching element 100 with piezoelectric-morphing beams surrounding a triangular actuator. The triangular actuator has a triangular electrically conductive conducting head 212 that is electrically coupled to a circuit node 220. Three piezoelectric-morphing beams 222, 224, 226 with respectively attached electrically conductive contact heads 212, 214, 216 are oriented around the conducting head 214. Each of the contact heads 212, 214, 216 can be selectively moved along a single axis of movement into contact with the conducting head 214 through application of Vpiezo to the separate nodes 116. Application of Vpiezo causes the respective piezoelectric-morphing beams 222, 224, 226 to stretch and push its respective contact head 212, 214, 216 into contact with the conducting head 114. The so-moved contact head 212, 214, 216 may be configured to axially move along a horizontal, vertical, incline, or decline plane.

Vpiezo is supplied to a 1-to-3 demultiplexer 242 as input A, and the demultiplexer 242 passes input A to one of three demultiplexer outputs X, Y or Z that are respectively connected to separate nodes 116. A selection signal generated by a controller 128 selects the demultiplexer output for Vpiezo. Controller 228 may be any type of microcontroller, microprocessor, digital signal processor (DSP) with access to non-transitory computer-readable media embodied with computer-executable instructions that, when executed, signal the selection of either output X, Y or Z. For purposes of embodiments discussed herein, computer-readable media includes memory in the form of volatile and/or nonvolatile memory, such as, for example, random access memory (RAM), read-only memory (ROM), flash memory, cache, or the like. Computer-readable media does not, however, include propagation signaling or other types of carrier waves for transmitting data.

In one embodiment, controller 228 provides demultiplexer 242 with binary values selecting one of the demultiplexer outputs X, Y, or Z of demultiplexer 242. For example, the control signal may include two binary numbers, with a binary value of “00” corresponding to demultiplexer output X, “01” corresponding to demultiplexer output Y, and “11” corresponding to demultiplexer output Z. Those skilled in the art will understand that selection of the demultiplexer 142 output for Vpiezo can be performed in numerous other ways, but such techniques need not be discussed at length herein.

While only three piezoelectric-morphing beams 212, 214, 216 are shown surrounding actuator 114, alternative embodiments may include any number of piezoelectric-morphing beams around actuator 114. In addition to varying the number of piezoelectric-morphing beams, the beams' orientation relative to actuator 114 may also vary in different embodiments, such as, for example, being positioned around actuator 114 in a square, rectangle, circle, trapezoid, pentagon, hexagon, or other type of geometric pattern. For example, six piezoelectric-morphing beams may surround actuator 114 in a hexagonal pattern, or ten piezoelectric-morphing beams may surround actuator 114 in a circular pattern. Alternatively, the piezoelectric-morphing beams 212, 214, 216 may be positioned to just one side of (instead of around) or at different angles to actuator 114.

In one embodiment, the piezoelectric-morphing beams 222, 224, 226 each move their respective contact heads 212, 214, 216 in a single axis of movement extending from based ends 200 through the contact heads 212, 214, 216 themselves, but the axis of movements may differ from each other. For example, piezoelectric-morphing beam 222 may push contact head 212 horizontally into contact with conducting head 114, while piezoelectric-morphing beam 224 may be re-oriented in a different configuration than shown in FIG. 2 and push contact head 214 vertically or at an angle into contact with conducting head 114.

Because the contact heads 212, 214, 216 and conducting head 214 are each manufactured from a conducting material (e.g., copper, aluminum, etc.), an electrical connection is made by connecting one of the contact heads 212, 214, 216 to the conducting head 224, allowing current to freely pass through the connection and out through node 220 without potentially being hindered by a switching element's voltage or current capacity. Thus, all that is needed to switch between different contact heads 212, 214, 216 is control voltage Vpiezo. Vpiezo can be applied to any of the piezoelectric-morphing beams 212, 214, 216, providing the ability to quickly switch between different voltage, current, or power sources connected to the different contact heads 212, 214, 216 that are provided to node 220 of the actuator 114.

To connect the piezoelectric-morphing beams 212, 214, 216 and the actuator 114 to other nodes of a circuit, one embodiment bonds electrical wiring to the contact heads 212, 214, and 216 and conducting head 224. Each contact head is physically connected to, or at least electrically coupled to, a circuit node 218A-C. Nodes 218A-C represent three different connection points to various nodes of a circuit or to different voltage or current supplies. Nodes 218A-C provide circuit points of contact that can selectively be connected to node 220 of the actuator 114. For example, contact head 212 may be moved into contact with conducting head 114, creating a connection between nodes 218A and 220. Demultiplexer 242 can then withdraw Vpiezo to node 116, consequently moving contact head 212 out of contact with conducting head 114, and then signal piezo-morphing beam 224 to axially pus contact head 214 into contact with conducting head 114, thereby creating an electrical connection between nodes 218B and 220.

To manufacture the illustrated switching element 100 in a chip, one embodiment couples the actuator 114 and piezoelectric-morphing beams 212, 214, 216 to a dielectric layer with a conductive connection or connecting via extending to underlying contacts. Connecting vias may be formed through dielectric materials using various etching techniques, e.g., isotropic, anisotropic, or the like. Alternatively, embodiments may couple actuator 114; piezoelectric-morphing beams 212, 214, 216; and their contacts 116 directly to one or more metallization layers in a semiconductor chip. Alternately, the switching element 100 may be manufactured as a MEMS device.

The illustrated switching element 100 can replace conventional transistors or other switching elements in a circuit that must be capable of handling the voltage or current loads of other more demanding components of a circuit. By being able to selectively switch between multiple contact heads 212, 214, 216 on the fly, the illustrated switching element 100 provides options for connecting terminals of electrical components to other circuitry or voltage/current supplies. This greatly benefits fault tolerance in chip manufacturing because if one of the supplies or circuits connected to a contact head 212, 214, 216 is faulty or damaged, an alternate circuit or supply can be used by applying Vpiezo across a non-faulty contact head.

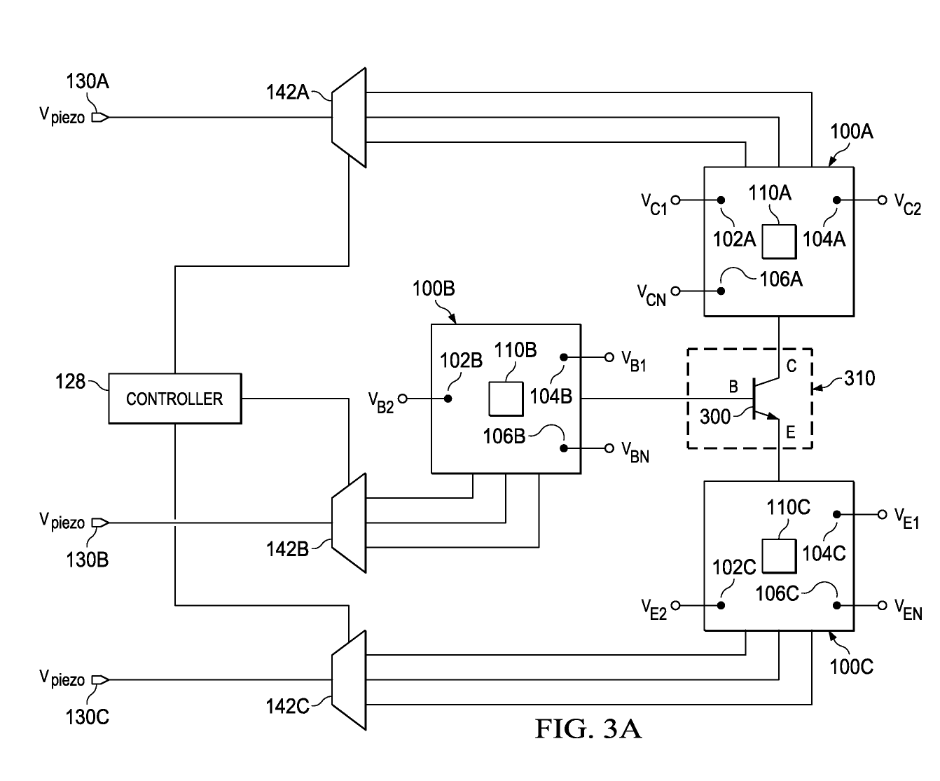

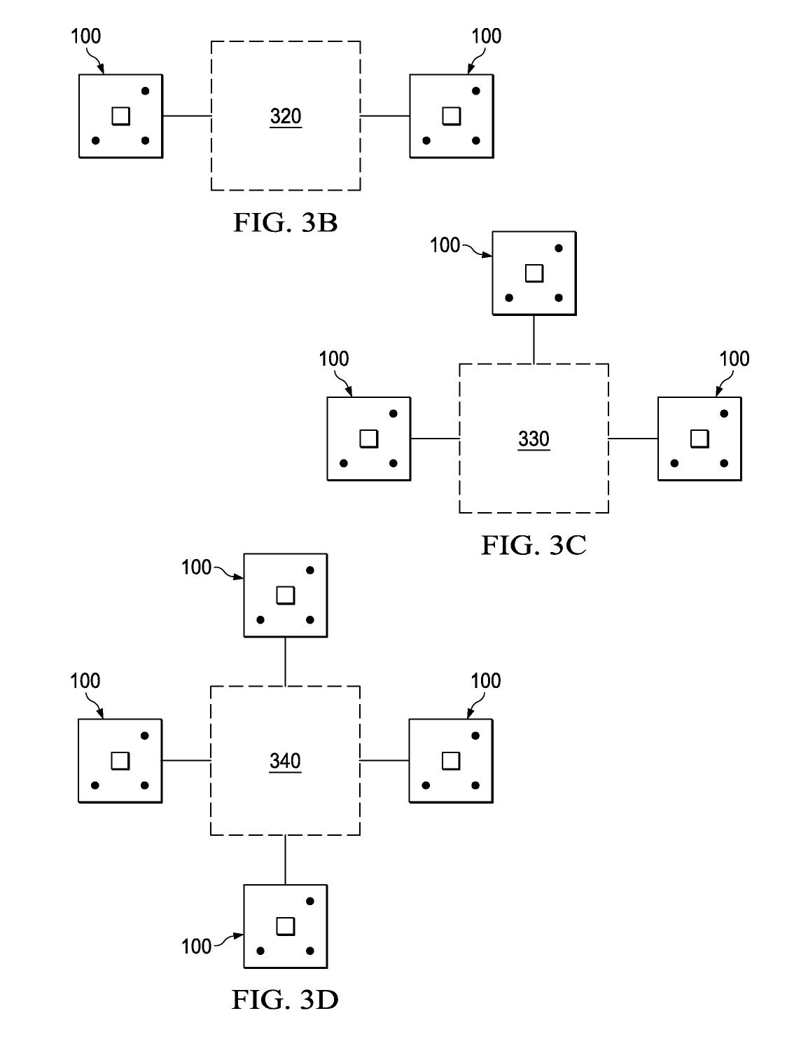

FIG. 3A illustrates three of the switching elements 100A-C shown in FIG. 2 respectively attached to the collector, base and emitter of an npn transistor 310. Piezoelectric-morphing beams 102A-C, 104A-C, and 106A-C are connected to various voltage, current, power, or circuit inputs, and actuators 110A-C are respectively coupled to the collector, base and emitter of transistor 310. The collector of transistor 310 can switch between V_{C1}, V_{C2}, V_{CN}; the base can switch between V_{B1}, V_{B2}, V_{BN}; and the emitter can switch between V_{E1}, V_{E2}, V_{EN}. Switching between the desired voltages is performed by applying control voltage Vpiezo 130A-C to piezoelectric-morphing beams of the switching elements 100A-C. While FIG. 3A shows a bipolar junction transistor (BJT), transistor 310 may be any kind of transistor, such as, for example but without limitation, a field-effect transistor (FET), a metal-oxide-semiconductor FET (MOSFET), or the like.

A controller 128 sends selection signals to demultiplexers 142A-C, which pass Vpiezo 130A-C to demultiplexer outputs coupled to contact nodes of the selected piezoelectric-morphing beams 102A-C, 104A-C, and 106A-C. For piezoelectric multiplexer 100A, control unit 128 may signal demultiplexer 142A to pass Vpiezo 130A to one of three contacts connected to piezoelectric-morphing beams 102A, 104A, and 106A. Vpiezo 130A will cause the selected piezoelectric-morphing beam 102A, 104A, or 106A to move toward actuator 110A along a single axis of movement and thereby create an electrical connection that enables one of input voltages V_{C1}, V_{C2}, V_{CN} to be supplied to the collector terminal of transistor 310. Vpiezo 130B will cause the selected piezoelectric-morphing beam 102B, 104B or 106B to move toward actuator 110B along a single axis of movement and thereby create an electrical connection that enables one of input voltages V_{B1}, V_{B2}, V_{BN} to be supplied to the base terminal of transistor 310. Vpiezo 130C will cause the selected piezoelectric-morphing beam 102C, 104C or 106C to move toward actuator 110C along a single axis of movement and thereby create an electrical connection that enables one of input voltages V_{E1}, V_{E2}, V_{EN} to be supplied to the emitter terminal of transistor 310.

A transistor cell can be manufactured that includes transistor 310 and one or all of switching elements 100A-C connected to terminals of the transistor 310. The transistor cell is capable of switching between multiple sources at the collector, base and emitter terminals. This new transistor cell may be manufactured as a discrete component, in a semiconductor chip, or in a MEMS device. The transistor cell (i.e., transistor 310 and one or all of piezoelectric multiplexers 100A-C) enables multiple input combinations to the transistor 310, allowing it to effectively function as multiple transistors. As a result, the transistor 310 can continuously be used and switched between different configurations, instead of having to just sit idly and take up space on a chip or a MEMS device when reverse biased. When used in electrical devices (e.g., cell phone, medical device, power electronics, etc.), the transistor cell improves the fault tolerance of these devices by providing a programmatically selectable transistor that can switch to alternative transistor terminal inputs whenever faults are detected in circuitry. For example, the collector can switch to V_{C2} whenever a fault is detected with V_{C1}.

The illustrated embodiments show input voltages selectively received at the collector, base, and emitter of transistor 310. Current may alternatively or additionally be received instead of voltage. Moreover, the piezoelectric-morphing beams 102C, 104C and 106C of piezoelectric multiplexer 100C for the emitter may be configured to not receive inputs but instead provide outputs to one of three different circuit connection points. So instead of receiving V_{E1}, V_{E2}, V_{EN}, piezoelectric-morphing beams 102C, 104C and 106C are each coupled to different circuit nodes, and the application of Vpiezo 130 selectively connects the emitter to one of the nodes. For the sake of clarity, however, embodiments are discussed herein as receiving voltage inputs, but embodiments fully contemplate receiving and providing voltage or current inputs and outputs.

Switching elements 100 may be added to terminals of electrical components other than transistors to create other types of electrical component cells. FIG. 3B illustrates a block diagram of a cell with two piezoelectric multiplexers 100 electrically coupled to a two-terminal electrical component, such as a diode, a capacitor, an inductor, a resistor, a transformer, or the like. FIG. 3C illustrates a block diagram of a cell with three switching elements 100 electrically coupled to a three-terminal electrical component, such as a transistor, thyristor, or the like. FIG. 3D illustrates a block diagram of a cell with four switching elements 100 electrically coupled to a four-terminal electrical component, such as a transformer, bridge rectifier, DC-to-AC inverter, or the like. Though multi-terminal electrical components are shown, the switching element 100 can alternatively be used to switch between disparate loads of a circuit. For example, the switching element 100 can be used to switch application of a particular voltage from the nodes of one transformer to the nodes of another.

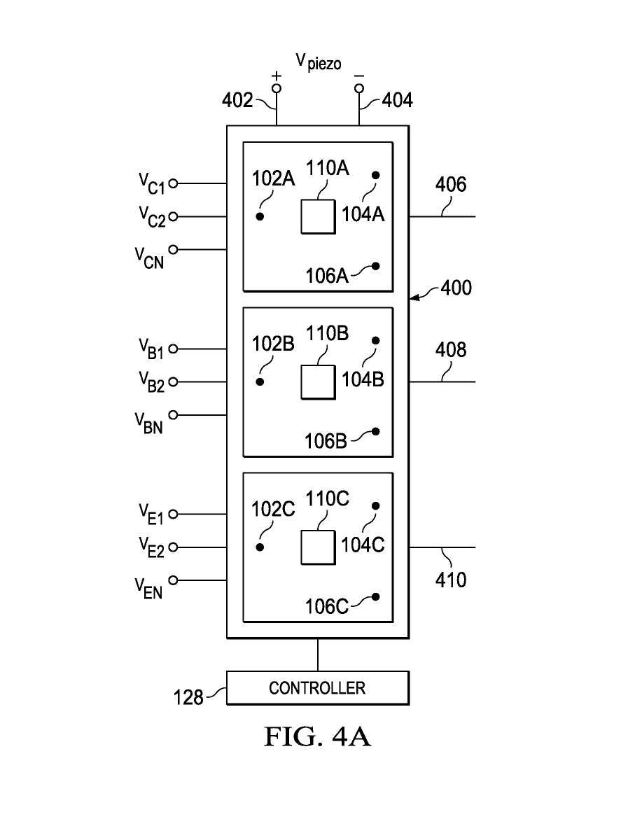

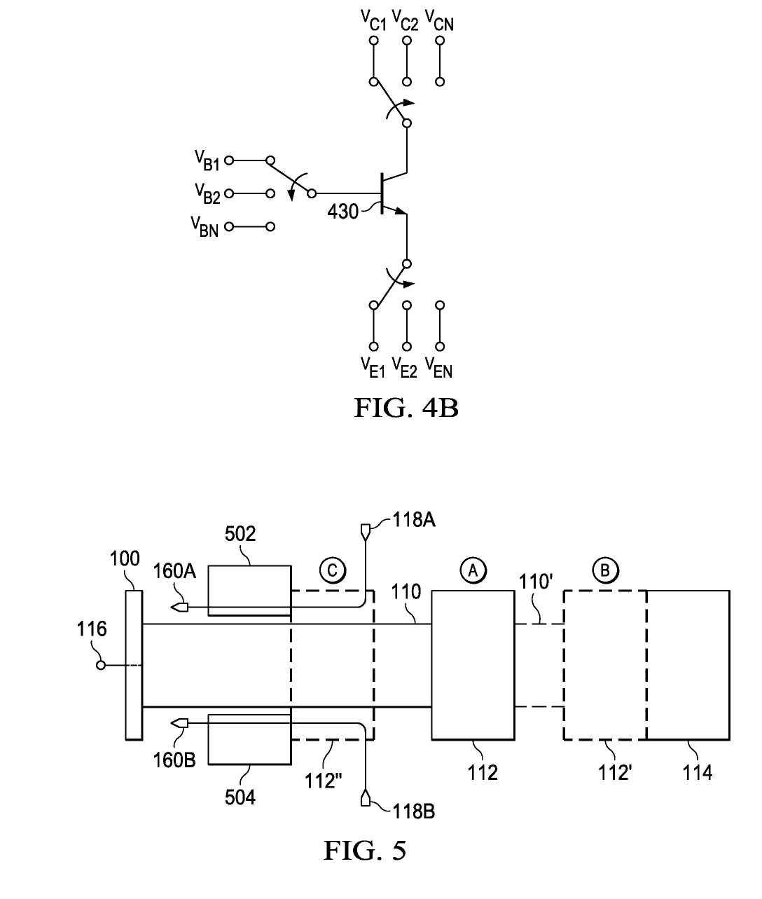

FIG. 4A is a block diagram of a transistor cell with multiple switching elements 100A-C embodied in a semiconductor chip 400. FIG. 4B the schematic functionality of the transistor cell embodied on a semiconductor chip 400 shown in FIG. 4A. Looking initially at FIG. 4A, the transistor cell receives three inputs for each switching element 100. Voltage inputs V_{C1}, V_{C2}, V_{CN} are electrically coupled to piezoelectric-morphing beams 102A, 104A and 106A, respectively; voltage inputs V_{B1}, V_{B2}, V_{BN} are electrically coupled to piezoelectric-morphing beams 102B, 104B and 106B, respectively; and voltage inputs V_{E1}, V_{E2}, V_{EN} are electrically coupled to piezoelectric-morphing beams 102C, 104C and 106C, respectively. Actuators 110A-C are respectively coupled to the collector, base and emitter of the transistor 430.

The semiconductor chip 400 receives a control voltage Vpiezo across inputs 402 and 404, and Vpiezo is selectively applied to the bimorph beams by signaling of controller 128, which may communicate selection signals directly to the semiconductor chip 400 or through a demultiplexer 142. Controller 128 selects which piezoelectric-morphing beams should receive Vpiezo, and when Vpiezo is applied, the selected piezoelectric-morphing beam physically stretches along a single axis of movement toward an actuator 110A, B or C, creating an electrical connection between one of the input voltages and a terminal of the transistor 430 shown in FIG. 4B. For example, the collector terminal is wired to the actuator 110A, and the controller 128 selects bimorph beam 102A connected to V_{C1} to receive Vpiezo, causing bimorph beam 102A to bend in to contact with actuator 110A and thus connect V_{C1} to the collector. In the same manner, the controller 128 can selectively connect the various piezoelectric-morphing beams of the collector, base and emitter to the different input voltages V_{C2-CN}, V_{B1-BN} and V_{E1-EN}.

Chip connections 406-410 provide connection points to the terminals of the transistor cell on semiconductor chip 400. Chip connections 406-410 are coupled to actuators 110A-C, respectively. FIG. 4B illustrates the transistor cell 430 schematically. The collector, base and emitter can selectively switch between different voltage inputs. FIGS. 4A and 4B show only one embodiment in which switching elements 100 are connected to a three-terminal BJT. Similar cells and semiconductor chips can be fabricated for other types of transistors (e.g., FET), as well as other multi-terminal (e.g., two-, three-, four-terminal, and the like) electrical components.

Though not shown for the sake of clarity, another embodiment will include damping capacitors between the actuator conducting head 114 and the bimorph beam contacts 132-136/532-536. Individual capacitors may be used for each bimorph beam 102-106 and 502-506, or a single capacitor can be used for each bimorph beam pair 102/502, 104/504 and 106/506. In the latter embodiment, one end of a capacitor will be connected to the actuator contact 140 and the other end will be connected to both beam contacts of the bimorph beam pair, e.g., contacts 132/532, 134/534 and 136/536.

In one embodiment, the piezoelectric-morphing beam 100 is configured to stretch along a single axis when Vpiezo is a certain positive voltage and also move in the opposite direction along the axis—i.e., shrink along the single axis—when Vpiezo is negative or below a certain threshold voltage. For example, application of a +5 mV Vpiezo may cause the piezoelectric-morphing beam 100 to extend 2 mm horizontally from a starting point, and application of a −5 mV Vpiezo may cause the piezoelectric-morphing beam 100 to shrink 2 mm horizontally in the opposite direction from the starting point. Thus, the piezoelectric-morphing beam 100 can move either direction away from a starting point along the single axis of movement.

FIG. 5 illustrates a switching element 100 configured to move in two directions along a single axis of movement, according to one embodiment. The depicted switching element 100 can move horizontally along an axis movement extending from the base layer of switching element 100 (shown as the end coupled to node 116) through the piezoelectric-morphing beam 100 and out of the contact head 112 toward the conducting head 114. The illustrated switching element 100 of this embodiment can move toward conducting head 114 of the actuator and toward the base layer, depending on the polarity or magnitude of Vpiezo applied at node 116. For example, a negative Vpiezo may cause the piezoelectric-morphing beam 100 to shrink along the axis of movement toward the base layer, and a positive Vpiezo may cause the piezoelectric-morphing beam 100 to stretch along the axis of movement toward the conducting head 114. Alternatively, other embodiments may direct movement of the piezoelectric-morphing beam 100 in one direction or the other using different magnitudes of voltage: for example, 5 mv in one direction, and 15 mv in the other direction.

Two additional actuator conducting heads 502 and 504 are included in the switching element 100 of FIG. 5. These conducting heads 502 and 504 are fashioned out of electrically conductive material and provide points of contact to additional circuit nodes. Thus, the piezoelectric-morphing beam 100 can be moved toward these additional conducting heads 502 and 504 through application of a particular Vpiezo (e.g., negative voltage Vpiezo) in order to bring the contact head 114 into contact with one or both of these conducting heads 502 and 504. When the contact head 114 touches the conducting heads 502 and 504, electrical pathways from 118A-160A and/or 118B-160A are created that allow the circuit points connected to the contact head 114 to be connected to the circuit points of the conducting heads 502 and 504. Thus, the switching element 100 can selectively be connected to three different conducting heads 114, 502, and 504 by strategically applying different voltage, current, or power values as Vpiezo at node 116.

To further illustrate this multi-contact switching element 100, FIG. 500 illustrates the contact head 114 being moved from a starting point show at “A,” along an axis of movement into contact with the conducting head 114 at point “B,” and back the other way along the axis of movement into contact with the conducting heads 502 and 504 at point “C.” During movement of the piezoelectric-morphing beam 100 between A, B, and C, the piezoelectric-morphing beam 100 stretches to move the contact head 112 into the positions shown by the dotted line contact heads 112′ and 112″.

Various modifications to the embodiments disclosed herein may be made without departing from the scope of the present disclosure and the claims provided below. The subject matter of the present invention is described with specificity herein to meet statutory requirements. The claimed subject matter might also be embodied in other ways, to include different steps or combinations of steps similar to the ones described herein, in conjunction with other present or future technologies.

What is claimed is:

1. A switching element, comprising:
an actuator with an actuator conducting head and an actuator stem;
a plurality of piezoelectric-morphing beams positioned in parallel to the actuator stem, each piezoelectric-morphing beam comprising a beam contact head made of a conductive material and a beam stem made of a piezoelectric material; and
a plurality of electrical contacts coupled to the beam stems and the actuator stem for receiving a selectively applied control voltage applied across a first piezoelectric-morphing stem and the actuator stem and causing a selected piezoelectric-morphing beam to stretch and move the beam contact head axially along a single axis of movement either horizontally or vertically move toward the actuator and create an electrical connection between the conducting head and the beam contact head of the selected piezoelectric-morphing beam.

2. The switching element of claim 1, wherein the plurality of piezoelectric-morphing beams are positioned in a geometric pattern surrounding the actuator.

3. The switching element of claim 1, wherein the geometric pattern comprises a triangle, square, rectangle, circle, trapezoid, pentagon, or hexagon, and the actuator is positioned in the middle of the piezoelectric-morphing beams.

4. The switching element of claim 1, wherein the actuator and the plurality of piezoelectric-morphing beams are etched out of a dielectric layer.

5. The switching element of claim 4, wherein the electrical contacts are electrically coupled to the piezoelectric-morphing beams through a conducting pathway or connecting via through the dielectric layer.

6. The switching element of claim 1, wherein a circuit is configured to selectively apply the control voltage to the plurality of piezoelectric-morphing beams.

7. The switching element of claim 6, wherein the circuit comprises:
a controller generating a selection signal indicating the selected piezoelectric-morphing beam, and
a demultiplexer receiving the control voltage and the selection signal and providing the control voltage to the electrical contact associated with the selected piezoelectric-morphing beam indicated in the selected signal.

8. The switching element of claim 1, wherein the electrical connection allows an input current received at the beam contact head of the selected piezoelectric-morphing beam to pass through the actuator conducting head.

9. The switching element of claim 1, wherein the conducting head of the actuator is electrically coupled to a first terminal of a transistor.

10. The switching element of claim 9, further comprising a second switching element with a second actuator electrically coupled to a second terminal of the transistor.

11. A system, comprising:
a piezoelectric multiplexer, comprising:
an actuator with an actuator conducting head and an actuator stem; and
a plurality of piezoelectric-morphing beams having a plurality of electrical contacts, each piezoelectric-morphing beam comprising a beam contact head made of a conductive material and a beam stem made of a piezoelectric-morphing material; and
a circuit configured to selectively apply a control voltage to one of the plurality of piezoelectric-morphing beams for causing the beam stem of the selected piezoelectric-morphing beam to move the beam contact head axially along a single axis of movement either horizontally or vertically toward the actuator and cause the beam contact head of the selected piezoelectric-morphing beam to create an electrical connection with the actuator conducting head.

12. The system of claim 11, wherein the circuit applies the control voltage to the selected piezoelectric-morphing beam to cause the beam stem of the selected piezoelectric-morphing beam to move the beam contact head axially along the single axis of movement.

13. The system of claim 11, wherein the electrical connection is created when the selected piezoelectric-morphing beam is horizontally or laterally moved into contact with the actuator conducting head.

14. The system of claim 11, further comprising a second actuator conducting head positioned in an opposite direction from the actuator conducting head along the single axis of movement, and wherein the piezoelectric-morphing beam is configured to move toward the second conducting head through application of an opposite polarity of the control voltage.

15. The system of claim 11, wherein application of the control voltage to the selected piezoelectric-morphing beam creates a piezoelectric effect that stretches the beam stem of the selected piezoelectric-morphing beam.

16. The system of claim 11, wherein the circuit comprises:
a controller generating a selection signal indicating the selected piezoelectric-morphing beam, and
a demultiplexer receiving the control voltage and the selection signal and providing the control voltage to the electrical contact associated with the selected piezoelectric-morphing beam indicated in the selection signal.

17. The system of claim 11, wherein the electrical connection allows an input current to pass through the beam contact head and the actuator conducting head.

18. The system of claim 11, wherein the conducting head of the actuator is electrically coupled to a first terminal of a transistor.

19. A switching element, comprising:
a first actuator with a first conducting head;
a second actuator with a second conducting head;
a piezoelectric-morphing beam positioned proximate to the actuator and comprising a beam contact head made of a conductive material and a beam stem made of a piezoelectric-morphing material, and
a controller configured to:
selectively apply a first voltage signal to the piezoelectric-morphing material to consequently cause the piezoelectric-morphing material to axially move the contact head along a single axis of movement either horizontally or vertically toward the first actuator and bring the beam contact head into physical contact with the first conducting head, and
selectively apply a second voltage signal to the piezoelectric-morphing material to consequently cause the piezoelectric-morphing material to axially move the contact head along the single axis of movement either horizontally or vertically in an opposite direction into contact with the second conducting head.

20. The switching element of claim 19, wherein the second voltage signal has a polarity opposite the first voltage signal.
